(19) United States
(12) Patent Application Publication
(10) Pub. No.: US 2002/0092766 A1
(43) Pub. Date: Jul. 18, 2002

(54) Sputtering deposition apparatus and method for depositing surface films

(76) Inventor: Curtis M. Lampkin, Merritt Island, FL (US)

Correspondence Address: Allen, Dyer, Doppelt, Milbrath & Gilchrist, P.A., Suite 1401, 255 South Orange Avenue, P.O. Box 3791, Orlando, FL, 32802-3791, US

(21) Appl. No.: 10/050,687

(22) Filed: Jan. 16, 2002

Related U.S. Application Data
(60) Provisional application No. 60/261,735, filed on Jan. 16, 2001.

(51) Int. Cl. C23C 14/35

(52) U.S. Cl. 204/298.22; 204/298.21; 204/298.2; 204/298.11; 204/298.26; 204/298.03; 204/298.19

(57) ABSTRACT

A sputter deposition apparatus for depositing a film onto a substrate includes a surrogate rotating magnetron includes an internal magnet and a wall thickness that permits a fringe magnetic field to support an electron cyclotron resonance. Auxiliary coating sources are modulated for depositing a desired sequence of material onto the substrate.

### CROSS REFERENCE TO RELATED APPLICATIONS

This application incorporates by reference and claims priority to Provisional Application having Serial No. 60/261,735 filed Jan. 16, 2001, for “SPUTTERING METHOD AND APPARATUS FOR DEPOSITING SURFACE FILMS,” commonly owned with the present invention.

### FIELD OF THE INVENTION

This invention generally relates to the physical vapor deposition of films in a vacuum, and in particular to the sputtering deposition of films using electron cyclotron resonance for coating a surface through sputtering.

### BACKGROUND OF THE INVENTION

Magnetron sputtering is an effective and economical thin film coating process for a variety of thin films and substrates such as glass or plastic. There are three types of sputter magnetron. The first two are the planar or conical type with a fixed sputter surface, and the rotating magnetron where the sputter material surface rotates through a sputter zone. Both must be pre-coated with the desired material before installation into the sputter deposition system. Such desired material can be a single element such as a metal or in the case of the planar type it can be a compound.

The third type of magnetron is the surrogate, as described in U.S. Pat. No. 5,405,517 which uses a rotating cylinder, disc, or belt to carry material deposited on it by auxiliary sources into the surrogate sputter zone to be re-sputtered onto a substrate. The surrogate magnetron need not be pre-coated before use but can be coated in place by auxiliary sources.

The surrogate magnetron has three advantages. First, no compound targets are needed so the selection of materials is much larger. The “target” is formed in place on the surrogate, by the auxiliary sources, as multiple layers in a “jelly roll” configuration. The second advantage is that material composition is controllable in real time. Thirdly, deposition is more rapid for compounds since most elements are sputtered as single elements from separate layers.

By way of example, consider negative ion/high energy neutral bombardment. A compound consists of a metal and a non-metal. Most metals are easily sputtered. However, when a non-metal is sputtered, it generates negative ions. Since the target is also negative, these negative ions are repelled with the full target voltage. They pass through the sputter plasma cloud and many are neutralized but lose little energy. These high-energy neutrals and negative ions then travel to the substrate and bombard it, damaging the film. For instance, when YBCO super-conductive films are sputtered, the negative ion bombardment is so severe that it can remove the deposited film and parts of the substrate also.

The negative ion/high energy neutral bombardment occurs with nearly all nonmetals. Transparent conducting oxides are also damaged by the negative oxygen ions formed. This avoids the negative ion (or high energy neutral) bombardment.

The teachings in the art suggest easing the bombardment in three ways. First, the metal can be sputtered, and the non-metal evaporated. Second, the sputter gas pressure can be increased to the point where the high-energy particles collide with gas molecules and thus lose their energy. But this raises costs by decreasing deposition rates and the high gas pressures often contaminate the film. Third, the substrate can be moved off to one side to avoid the ions completely. Negative ions/high-energy neutrals travel perpendicular to the target. But again the deposition rate is greatly reduced which raises costs.

A better solution to this negative ion bombardment is to significantly lower the magnetron target voltage thus lowering the energy of the negative ions. Microwave injection works well for this.

Injecting microwaves into the plasma requires a strong magnetic field. The teachings in the art employ solenoidal magnetic fields to add energy to sputter plasmas using the electron cyclotron resonance or ECR effect. For instance in U.S. Pat. No. 4,721,553 to Saito, the microwaves are fed through a cusp shaped magnetic field formed by opposing solenoidal magnetic fields and thence to the target for sputtering. The Saito method can produce low voltages but it cannot work with anything other than a disc shaped target and so is ineffective with a cylindrical magnetron or indeed any type of rotating surface, which can be used in the surrogate magnetron mode. And since the plasma is created away from the target it must be transported to the target. Ions are lost during transport, which makes it necessary to place the plasma creation area as close to the target as possible. This need for closeness causes the microwave feed-through window to be coated with sputtered material, which interferes with the microwaves.

Gesche et al, in U.S. Pat. No. 5,397,448, and Latz et al. in U.S. Pat. No. 5,531,877, inject microwaves through a feed slit adjacent a planar target. They also use a solenoid magnet surrounding the target to increase the magnetic field of the planar magnetron to the strength needed for electron cyclotron resonance to occur. The feed slit is very close to the target so that gas scatter of sputtered material will eventually migrate through the feed slit and coat the microwave window. This method also cannot be used with surrogate magnetrons.

Planar sputter magnetrons must use a low magnetic field in order not to erode narrow grooves in the target. Such narrow grooves decrease the material usage ratio, which is ordinarily 25%-30% unless rotating magnets are used. Even with rotating magnets strong magnetic fields in a planar magnetron are not necessary.

With rotating cylindrical magnets stronger magnetic fields can be used. But both planar and rotating cylindrical magnetrons must be pre-coated with the sputter material. This pre-coating is of such a thickness that it diminishes the magnetic field strength available.

Further consider sputter plasma dynamic impedance. Besides making the ECR effect possible, a strong magnetic field decreases the plasma dynamic impedance of the plasma. Dynamic impedance is the slope of the current voltage curve. If the dynamic impedance is low, then when extra current is drawn through the sputter plasma, the plasma voltage changes very little. Previous workers in the thin film field have used both microwaves and electron beam injection to lower sputter plasma voltage. But when significant plasma currents are drawn, as is necessary for high rate deposition, the plasma voltage increases negating the benefit of the electron or microwave injection. External solenoid magnets as mentioned previously do not decrease the plasma dynamic impedance as much as the strong internal magnet possible with a surrogate magnetron.

Besides the problem of negative ion bombardment, there is a second defect which sputtering shares with most other thin film deposition methods. This is the formation of three-dimensional growth, which includes the tendency of the arriving atoms to initially form small individual islands instead of a smooth two-dimensional film. After several monatomic layers are deposited the islands start to coalesce into a continuous film. But the initial island structure degrades the smoothness and continuity of crystal structure and causes small grains to form in the film

A recently developed technology called MEE or immigration enhanced epitaxy can reduce or suppress 3 dimensional island growths. Homma et al. (Appl. Phys. Lett. 68 (1) Jan. 1, 1996) have found that the order of the arriving atoms can be manipulated to improve the crystalline structure in compound sputtered films.

In this method, the compound is deposited in alternate monatomic layers. For example if one desired to deposited Gallium Arsenide, one would deposit a layer of Gallium one atom thick and then immediately deposit a layer of Arsenic one atom thick and then Gallium again and so on, building up the alternating layers until the desired thickness was achieved. The substrate must be heated to high temperatures to give the arriving particles enough energy to find their place in the growing film matrix. The separate monatomic layers fuse or react to form grains of GaAs. The resulting film is smoother, more continuous with better electronic properties.

There are presently only two deposition processes that can use the MEE technology. They include molecular beam epitaxy (MBE) and atomic layer epitaxy (ALE).

In MBE the desired elements are heated in high temperature vapor sources, which are aimed at the substrate and project molecular beams toward the substrate. Mechanical shutters alternately interrupt the flow of gallium vapor for example and then arsenic vapor to provide monatomic layers of each material continuing until the proper film thickness of Gallium Arsenide is achieved. MBE is a slow and expensive process. It can coat relatively small areas and it requires a very high substrate temperature to provide energy to the arriving atoms so that they can find move around and find their proper place in the growing crystal lattice. It can take 10 hours or more to achieve adequate film thickness on a substrate. Additionally, with high vapor pressure elements such as Arsenic, the shutter can never completely interrupt the atoms and as much as 20% of the Arsenic atom flux may still reach the substrate during the time sequence intended for Gallium only. This interferes with the purpose of the effort.

ALE (atomic layer epitaxy) rotates a substrate under multiple chemical vapor deposition beams. It also serves only relatively small substrates, requires high substrate temperatures, uses toxic materials, is slow, and is relatively expensive.

Another technology, referred to as quantum well (QW) structures, can greatly enhance the electronic performance of semiconductors. It also involves multi-layering of material but here the different material layers are kept separate. In this case 10 to 1000 monatomic layers of different materials are stacked to a desired thickness. The resulting layers “channel” electrons in a 2 dimensions flow, which has electronic advantages. As with MEE, the only prior art deposition methods that can make such QW structures are usually MBE and ALE.

McKelvey in U.S. Pat. Nos. 4,356,073 and 4,444,318 pre-attach thick slabs of multiple materials around the periphery of a rotatable but not continuously rotating cylindrical magnetron for deposition of multi-layered materials. These patents can deposit only thick multiple layers onto a stationary substrate or offer the ability only to change materials easily while sputtering single layers onto moving substrates. The pre-attached materials are so thick that they weaken even the strongest magnets to the point where they cannot easily support an ECR plasma without external magnetic means. They have no provision either for continuous rotation or for sensing of rotation position. Additionally, the clamps that clamp the separate slabs can be sputtered themselves, and thus contaminate the film, unless care is taken to position the slabs accurately in the magnetic field and to allow no rotation during sputtering.

This invention allows a surrogate magnetron to economically deposit improved thin films at high rates with little negative ion bombardment, with sequentially modulated material flux for mobility enhanced epitaxy, with less need for high substrate temperatures, and to deposit quantum well structures onto substrates.

### SUMMARY

In view of the foregoing background, there is a need to expand the capabilities of the rotating surrogate magnetron. As described in U.S. Pat. No. 5,405,517, the disclosure of which is herein incorporated by reference, advantages of the rotating surrogate magnetron include: the real time control of elemental ratios during sputter deposition; the ability to use pure elements instead of expensive compound targets; and the elimination of toxic gases in most cases. Desired improvements are addressed by the present invention and include: the ability to inject microwaves into the sputter plasma without the need for external magnets thus allowing the use of the surrogate magnetron with microwave energy injection into the sputter plasma; a significant decrease in sputter plasma impedance allowing lower sputter plasma voltages even at high plasma discharge currents; the significant decrease in thin film bombardment damage by negative ions and high energy neutral particles because of such low plasma voltages; the ability to modulate deposition flux in a sequential controlled fashion to allow the migration enhanced epitaxy method for improving thin film quality; the ability to deposit quantum well structure in large areas; and the ability to provide all the above advantage with high deposition rates providing a significant improvement in the economics of the deposition process.

Although the description above contains specificities, these should not be construed as limiting the scope of the invention but merely as providing illustrations of some of the preferred embodiments. For example, cathodic arc deposition systems can be used as auxiliary sources instead of sputter magnetrons. The only requirement is that the auxiliary source can be modulated to vary the depositing flux with time except in the case of a vapor source. Vapor sources can be used in combination with any desired auxiliary or surrogate deposition source. Disc auxiliary and surrogate magnetron can be used when desired. In a disc arrangement, multiple auxiliary magnetrons or cathodic arc sources can be used in combination with vapor sources. The invention does not constrain the use of other technologies such as bipolar pulsing of power supplies for reactive sputtering or gas pulsing when desired. Providing that the deposition profiles of the auxiliary and surrogate sources can be designed for a sufficiently narrow deposition footprint, more than two sectors can be used on the surrogate magnetron.

If gas flows emanating from the gas shields are excessive, extra vacuum pumping capability can be added to the vacuum chamber in the area of the gas shield to counteract these effects.

While a substrate as herein described is shown as a single planar sheet by way of example, it can be seen that any convenient size and shape and number can be used. Other substrate supports known in the art can also be used as long as they can protect the depositing thin film from microwave absorption when desired. Thus the scope of the invention should be determined by the appended claims and their legal equivalents rather than by the examples given.

One object of the present invention is to provide a method whereby microwaves can be fed to a sputter magnetron without the need for external solenoidal magnetic fields. Another object is to provide an apparatus whereby microwaves can be injected into the sputter plasma of a surrogate magnetron. It is another object to significantly lower the magnetron sputter discharge plasma voltage to suppress formation of damaging negative ions during deposition of compound thin films. Further, means are provided to increase the magnetic field of a surrogate rotating sputter magnetron wherein the plasma impedance of said sputter plasma discharge is significantly lowered whereby said plasma discharge voltage is significantly lowered at higher operating powers. Yet another object is to provide an apparatus and method to enable the use of the MEE (mobility enhanced epitaxy) technology during sputtering to suppress island growth during the initial stages of thin film growth, to provide an improved method to modulate material flux ratios of component materials which form a compound thin film on a substrate, to provide improved material flux modulation methods whereby the run times of auxiliary and surrogate material deposition sources are extended thus improving process economics, to provide a faster deposition method for compound thin films which proportionately eases the vacuum level needs of the deposition system thus lowering its cost, to provide a method to make QW (quantum well) film structures more rapidly and economically, to eliminate the effect of negative ions thus allowing the natural (and optimum) sputter atom energies of 1 to 10 electron volts to improve film quality with less need for high substrate temperatures, to deposit thin films with superior qualities more suitable for optical, mechanical, and electronic use with less need for toxic gases, and to deposit thin films with superior qualities at high rates suitable for large area coating applications such as solar cells, batteries, flat panel displays, fuel cells, and electro-chromic windows. Further objects and advantages of this invention will become apparent from a consideration of the drawings and the accompanying description.

These and other objects, features and advantages according to the present invention are provided by a sputter deposition apparatus for depositing a film onto a substrate, wherein the apparatus comprises a surrogate rotating magnetron having an internal magnet proximate one side of a wall for providing a magnetic field having a field strength for confining a sputter plasma capable of absorption of microwave energy, and wherein the wall has a thickness sufficient for allowing a fringe magnetic field to support an electron cyclotron resonance on an opposing side thereof.

A second embodiment includes a sputter deposition apparatus comprising means for modulating a material flux from at least one auxiliary coating source onto a wall of the surrogate rotating magnetron in a desired sequence for producing sectors of auxiliary material, wherein the surrogate rotating magnetron deposits a controlled sequence of auxiliary materials onto a substrate. Yet another embodiment includes an auxiliary coating source having heating means for melting a coating material and means for retaining the molten material until solidified, the retaining means operable for rotating the solidified material to a position suitable for coating a surface.

A method aspect of the present invention includes depositing material onto the surrogate magnetron in angular sectors, which then sputter off to give a rapid sequential deposition of separate monatomic layers for mobility, enhanced epitaxy (MEE). This also provides for the rapid deposition of quantum well layered structures. Yet another method of the present invention includes the use of a vapor source, which can continuously coat the surrogate magnetron, along with modulated auxiliary sources having a continuous phase shift in the modulation frequency. The phase shift provides a sweeping sputter action to remove unwanted build up of material on the surrogate magnetron surface.

### BRIEF DESCRIPTION OF THE DRAWINGS

A preferred embodiment of the present invention as well as others that will become more apparent by referring to the following detailed description and drawings are herein described in which:

FIG. 1 is a diagrammatical side view of one preferred embodiment of the present invention;

FIG. 2A is a partial side view illustrating a phase shift portion of the embodiment of FIG. 1;

FIGS. 2B through 2D are partial cross-section views illustrating a phase shift sequence in sputtered material film and vapor film on a surface of a surrogate rotating magnetron;

FIG. 3A is a partial perspective view of a magnetron of FIG. 1 illustrating an improved film uniformity;

FIG. 3B is a cross-section view taken through an axis of rotation of FIG. 3A;

FIG. 4A is a partial diagrammatical view of a second embodiment of the MEE film deposition device of FIG. 1;

FIG. 4B illustrates transition widths at locations A through F of FIG. 4A;

FIG. 4C illustrates a sputter rate sequence for an MEE;

FIG. 4D is a partial cross-section view of an MEE film structure for a stationary substrate;

FIG. 4E is a partial cross-section view of an MEE film structure for a moving substrate;

FIG. 5A is a diagrammatical top view of one disc surrogate magnetron of the present invention;

FIG. 5B is a side view of the embodiment illustrated in FIG. 5A; and

FIG. 6 is a diagrammatical illustration of one embodiment for an ITO deposition in keeping with the teachings of the present invention.

### DETAILED DESCRIPTION OF PREFERRED EMBODIMENTS OF THE PRESENT INVENTION

The present invention will now be described more fully with reference to the accompanying drawings in which preferred embodiments of the invention are shown and described. It is to be understood that the invention may be embodied in many different forms and should not be construed as limited to the illustrated embodiments set forth herein. Rather, the applicant provides these embodiments so that this disclosure will be thorough and complete, and will convey the scope of the invention to those skilled in the art. Like numbers refer to like elements there through.

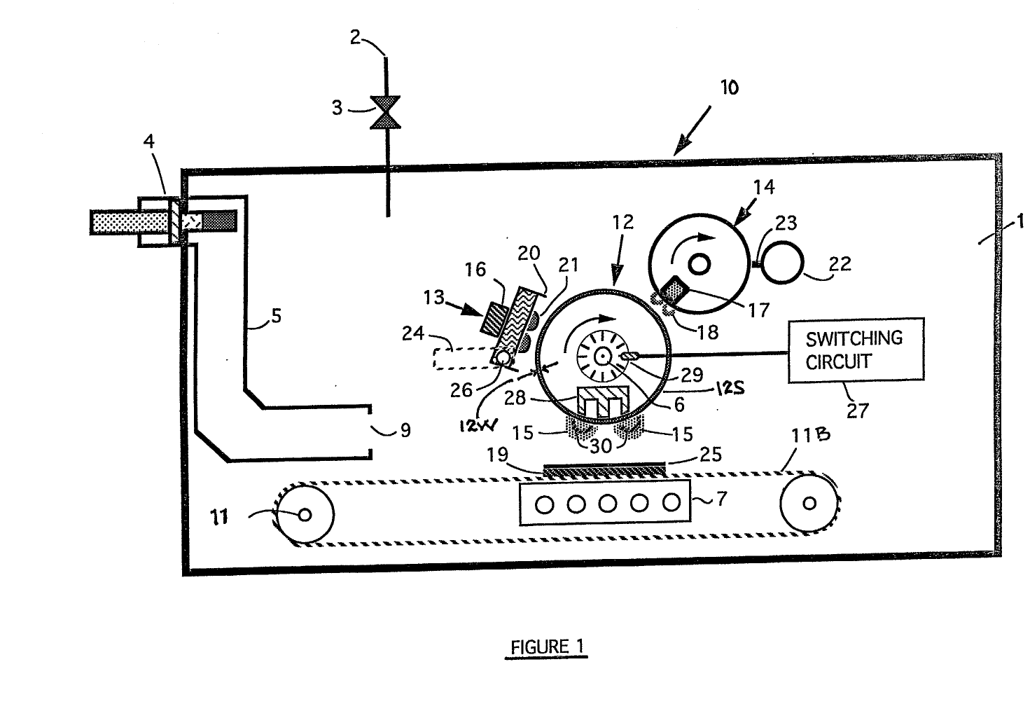

FIG. 1 illustrates a side cross-section view of a deposition apparatus/system 10 suitable for depositing a thin film having 2 elements with non-reactive sputtering. For clarity only 2 auxiliary sources are shown. More auxiliary sources of any applicable type can be added up to the mechanical limits of the system 10. With suitable gas shields placed around selected auxiliary and surrogate sources, reactive sputtering can be done with any selected source.

A vacuum chamber assembly 1, of any convenient shape, contains a surrogate rotating cylindrical magnetron assembly 12 (shown in an end view). It also contains vacuum pumps, control valves, and gauges, which are not shown. Gas inlet 2 and 2i and valves 3 and 3i control sputter gas delivered to plasma 15. As shown, auxiliary planar magnetron 13 is configured to deposit a low melting point metal such as gallium onto surrogate 12. Magnetron 13 can be rotated about pivot 26 into a horizontal refill/melting/storage position 24. When magnetron 13 is in horizontal position 24 then heating means 16 can be used to melt a fresh charge of metal pieces or re-melt the metal when needed to re-flatten its surface. Lip 20 contains the molten metal and prevents it from spilling out. In the position shown, auxiliary magnetron 13 can sputter deposit material onto surrogate magnetron 12. Auxiliary magnetron 13 can be cooled to the required temperature to keep the target metal solid. Auxiliary magnetron 13 can be placed in horizontal position 24 for storage or in case of a power failure to prevent melted metal from escaping. With other materials, auxiliary magnetron 13 can be pre-coated externally and can be a planar magnetron, a rotating magnetron, or a cathodic arc source.

In one embodiment, herein described by way of example, an auxiliary rotating cylindrical sputter magnetron 14 is configured for coating in-place, with a material, which vaporizes at moderate temperatures. Vapor delivery slit 23 conducts vapor from source 22 to the surface of temperature controlled rotating surrogate magnetron 12 where it continuously condenses to form a film of the desired thickness. Auxiliary cylindrical rotating magnetron 14 then sputters the condensed film onto surrogate rotating magnetron 12. Rotating magnetrons 16 and 14 as well as pivot 26 have shafts extending through the side of vacuum chamber 1 by means of rotating shaft seals not shown. Coolant and electrical power connections fed through these shafts that are also not shown.

Shaft angle sensing means 29 sends control signals to switching circuit 27 which in turn controls the power supplies (not shown) for auxiliary magnetrons 13, 14 and surrogate magnetron 12. The relative angular positions of plasmas 15, 18 and 21 determine the angular switching positions of the power level changes for the power supplies for magnetrons 12, 13 and 14

A substrate 19 is transported by transport means 11 on conductive mesh belt 11B to surrogate magnetron plasma 15 to receive material sputtered from surrogate magnetron 12. Substrate 30 can be stationary or moving. Substrate 19 can be heated if desired by heating means 7. Conductive mesh belt 11B supporting substrate 19 prevents microwave energy from being absorbed by the film 25 on substrate 30. Conductive mesh belt 30 being semitransparent also allows radiant heat from heating means 7 to heat substrate 19.

Microwave energy generated external to the vacuum chamber by a microwave source (not shown) is fed by means of feed-through means 4 to input waveguide 5 and thence to antenna 9. Antenna 9 can be a slot or a horn or an inductive loop antenna or any other applicable energy-radiating device. Antenna 9 transmits microwave energy to plasma 15 where much of the microwave energy is absorbed, lowering the discharge voltage of sputter plasma 15. Microwave energy can also be fed directly into the shaft 6 with proper design and thence to plasma 15 if desired.

Magnet 28 inside surrogate magnetron 12 creates and confines plasma 15. The magnet 28 is of sufficient strength to create an ECR flux surface 30 of sufficient size when the plasma 15 is excited by microwaves. Auxiliary magnetrons 13 and 14 also have magnets 17 for their sputter plasma zones 18 and 21. Magnets 17 need not necessarily have sufficient strength to generate an ECR surface unless so desired.

Surrogate magnetron 12 sputter deposits, in a controlled manner, the materials received by auxiliary sources 13 and 14 onto substrate 19 forming thin film 25. Surrogate magnetron 12 could be replaced by a rotating cathodic arc source having magnetic guidance of the arc and suitable deposition flux uniformity. Any auxiliary source can be replaced by a cathodic arc source with magnetic arc guidance and suitable flux uniformity.

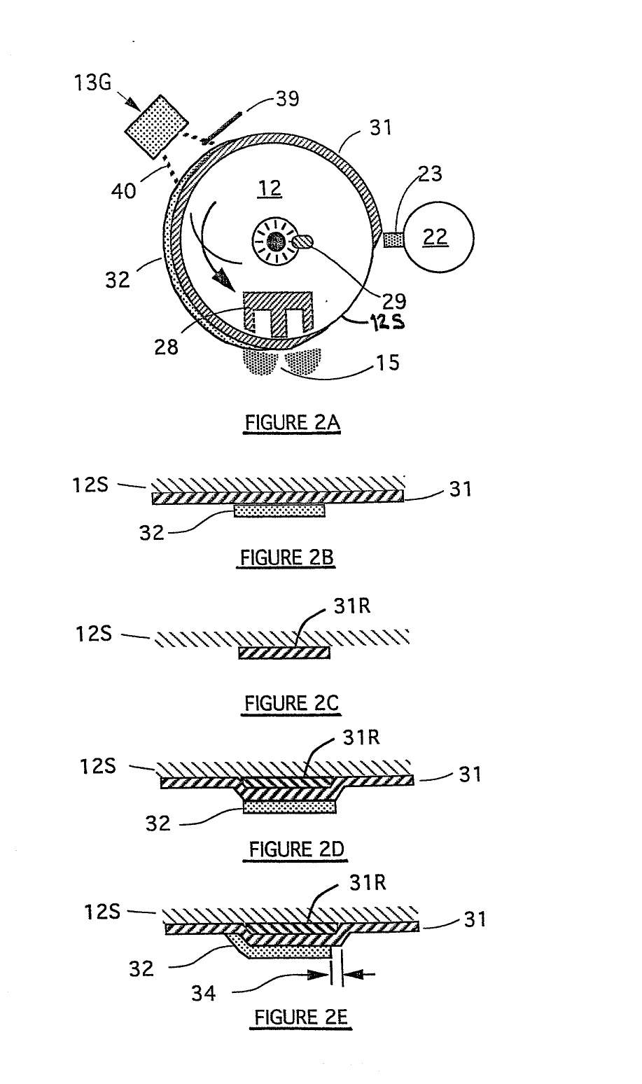

FIG. 2A illustrates an end view of a rotating cylindrical surrogate magnetron configured being coated continuously by vapor source 22 with material 31 while having material sector 32 deposited atop material 31 in a modulated manner by auxiliary source 13G. Source 13G can be a magnetron or cathodic arc or any source capable of temporal modulation of its uniform material flux beam 40. FIG. 2B illustrates (in flat linear form for clarity of illustration) a 180 degree sector of sputtered material 32 sitting atop film 31 which covers a complete rotation of 360 degrees. FIG. 2C illustrates that after passing through sputter plasma 15, a 180 degree sector 31R of the film 31 remains, having been protected by sector 32. FIG. 2C illustrates after another rotation is made through sputter plasma 15 and another sector of material 32 is deposited on another condensed vapor film then we see the condensed film 31 built up twice as thick where remnant 31R is. FIG. 2D illustrates another freshly sputtered sector of material 32 atop remnant 31R and freshly condensed film 31 just before it enters sputter plasma 15. FIG. 2E illustrates a freshly sputtered sector of material 32 partially revealing some of remnant 31R.

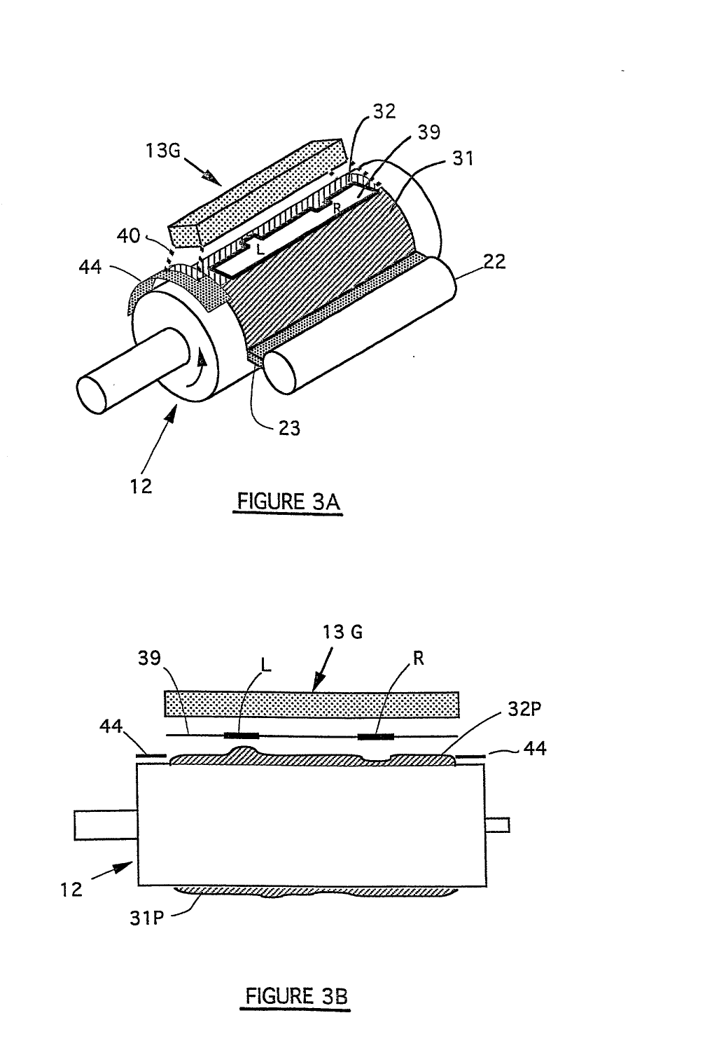

FIG. 3A is a perspective view of the placement of end shields 44 and trim tabs 39 that serve to improve the uniformity of the sputtered film 32 from auxiliary source 13G onto surrogate 12.

FIG. 3B illustrates in profile 32P how a possible sputtered film 32 might appear. The vertical scale is greatly exaggerated for illustration. There might be a low spot L and high spot H. Trim tab 39, in this illustration, can have a notch at L to allow slightly more material to be deposited to fill the low spot L. Similarly tab H can intercept more material to decrease high spot H. Trim tab 39 can be one piece or several pieces advantageously positioned

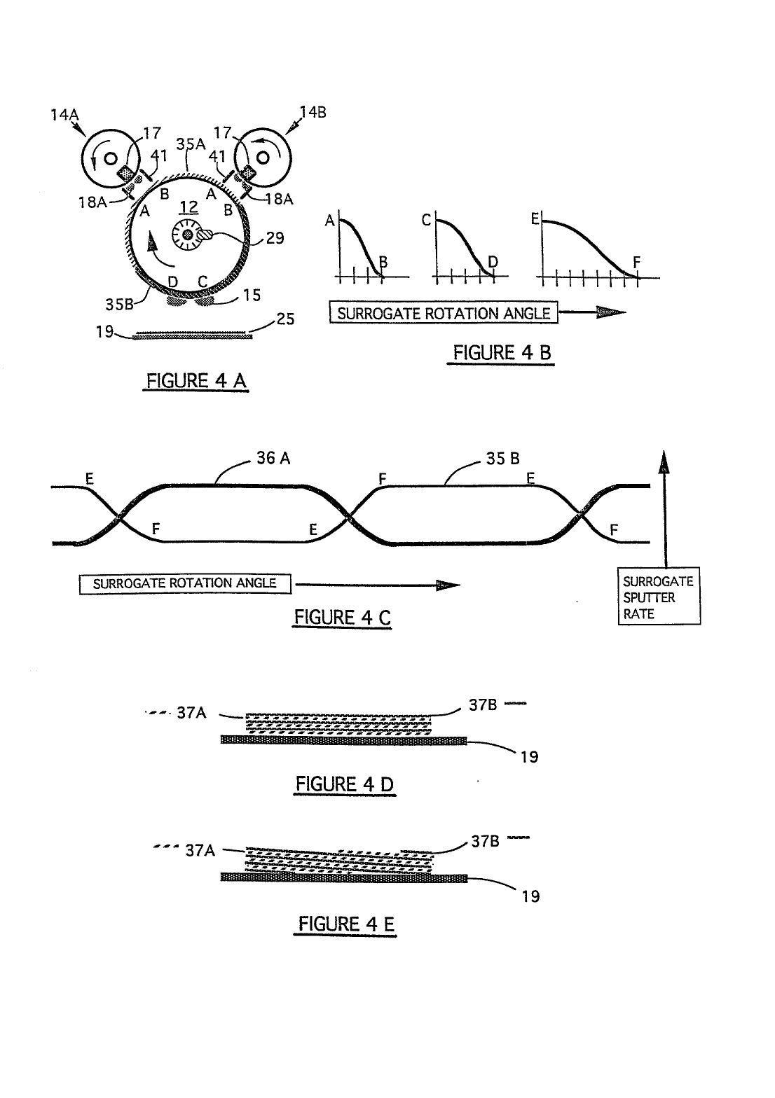

FIG. 4A illustrates a configuration for depositing sectors with 2 modulated auxiliary sources. No vapor source coats the surrogate. For illustration they are shown as continuously rotating cylindrical magnetrons. Source 14A will sputter material sectors 35A onto rotating surrogate 12. This sputtered material will have an edge sharpness or transition width AB as shown in FIG. 4B. This is a measure of the profile of sector edge 35A. It is related to the width of magnet 17 and collimator 41. Auxiliary source 14B will have an identical transition width AB. Rotating surrogate magnetron 12 will have a similar edge transition CD. In this case CD is the sputter rate as would be seen by the substrate 19 if sector 35A had a zero width or perfectly sharp edge as it entered sputter zone 15. The combined transition width EF as shown in FIG. 4B is a function of transition widths AB and CD. FIG. 4C illustrates graphically the sputter rates 36A and 36B as their corresponding sectors 35A and 35B continuously rotate through sputter plasma 15. In this case one continuous rotation is shown. FIG. 4D illustrates the relationship between separate layers for a stationary substrate. FIG. 4E illustrates the relationship between separate layers for a moving substrate.

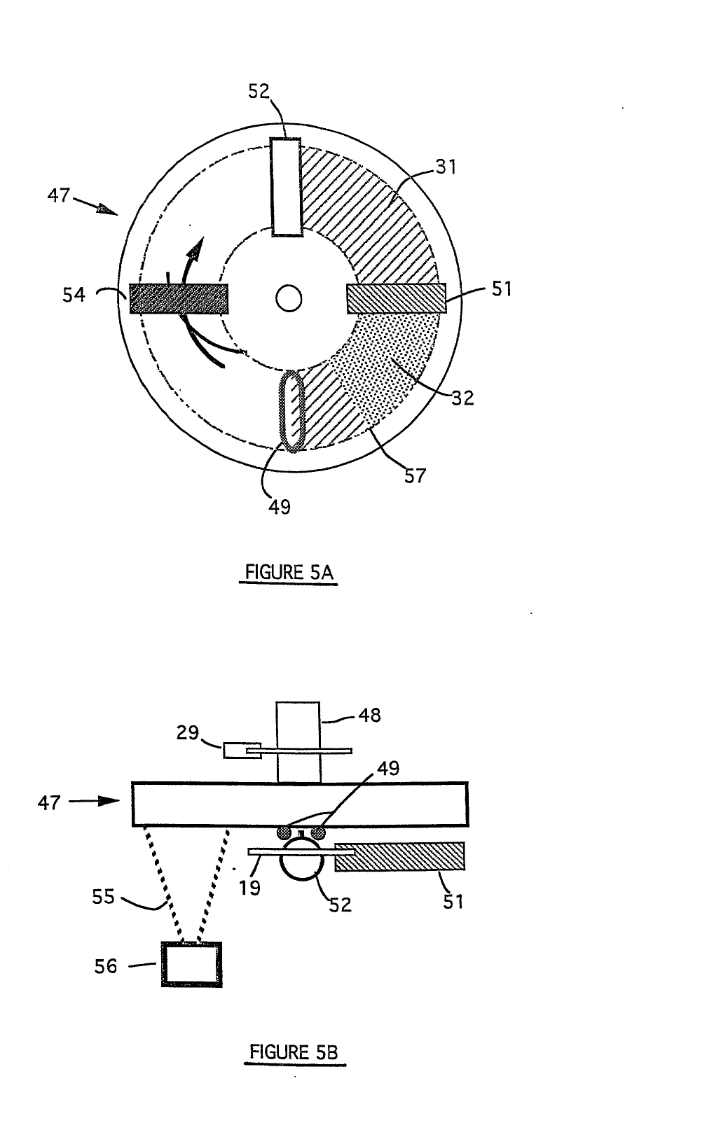

In an alternate embodiment of the system 10 with rotating cylindrical magnetrons, FIG. 5A illustrates a top view of a rotating disc surrogate magnetron 47 similar in operation to the system of FIG. 2A. Vapor source 52 lays down a condensed vapor 31. Auxiliary modulated source 51 covers 31 with a sector of material 32. The boundary between them 57 is shown on its way to surrogate sputter plasma 49. FIG. 5B illustrates a side view of the same apparatus. Here we also see remote vapor source 56 which can deposit material in flux beam 55 in place of vapor source 52. Surrogate magnetron 47 has shaft angle sensing means 29 mounted onto shaft 48. Vapor source 52 can be replaced with another modulated auxiliary source.

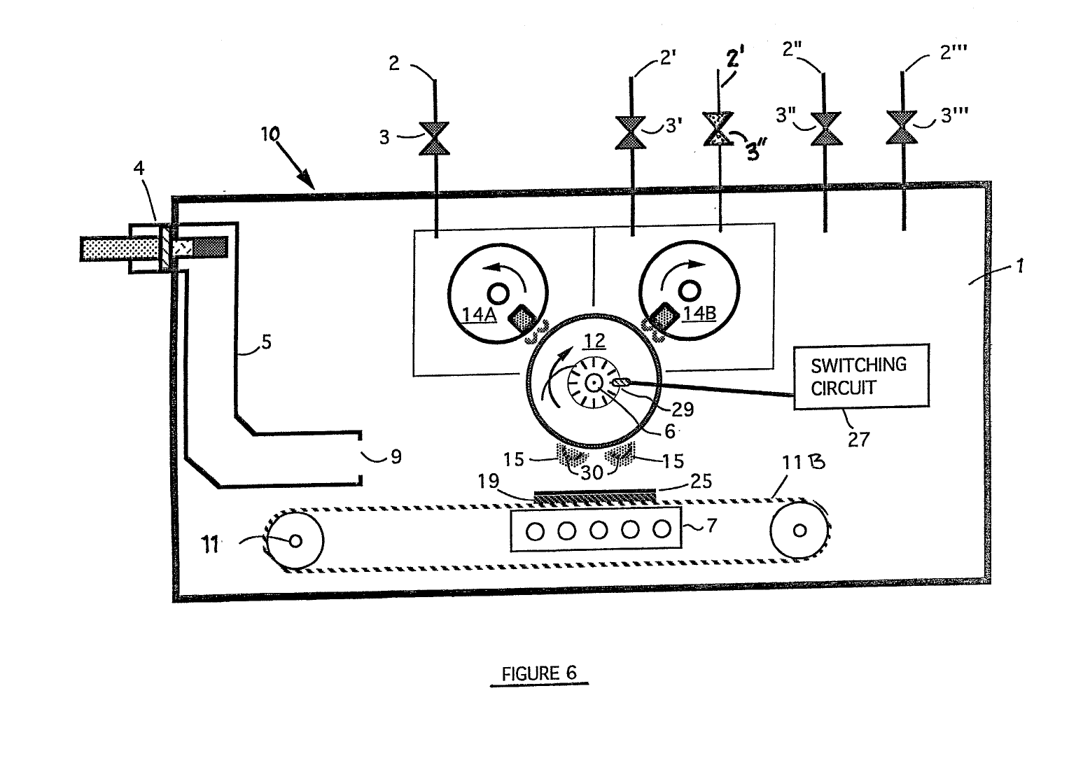

FIG. 6 illustrates an apparatus suitable for reactive sputtering of a material such as Indium Tin Oxide (ITO). It has 2 auxiliary sources 14A and 14B surrounded with gas shields 38. Each gas shield has a sputter gas feed line 2 and 2i along with control valves 3 and 3i. Chamber 1 has a sputter gas feed line 2ii and control valve 3ii and a reactive gas feed line 2iii with control valve 3iii. Surrogate rotating magnetron 12 receives material from auxiliary sources 14A and 14B. All sources have power supplies, which are controlled by shaft angle sensing means 29 along with switching circuit 27. Surrogate 12 sputter deposits material onto substrate 19 forming thin film 25. Substrate 19 can be stationary or moving and can be supported or transported by belt 11 and transport means 10. Substrate 19 can be heated if desired by heating means 7. Sources 12, 14A, and 14B can be modulated or operated at constant power as desired.

In operation, by way of example, for the deposition of Gallium Arsenide, reference is again made to FIG. 1. For clarity, the geometric aspect of this invention will be shown first. Then the microwave interactions will be described. Referring to FIG. 1, auxiliary magnetron 13 is placed in horizontal position 24 and loaded with gallium, taking care to prevent oxidation or other contamination. Vapor source 22 is loaded with arsenic granules. Loading of either source can be done manually or with automatic loading means. The gallium is melted in a vacuum while lip 20 retains the molten metal on the magnetron surface. Coolant is then run through pivot/support tube 26 into magnetron 13 to solidify the Gallium. Magnetron 13 is then rotated in position for sputtering. While under vacuum and with magnetron 14 rotating, vapor source 22 is heated to between 250 and 600 degrees C. No other magnetrons are operating. Vapor from source 22 is conducted through slit 21 and condensed onto the surface of cylindrical magnetron 24. Slit 21 is placed close to the cooled surface of magnetron 24, which collects the arsenic with very little vapor leakage into the rest of the system 10. Vapor source 22 can be operated continuously or in batch mode. In batch mode, when magnetron 24 is coated to sufficient thickness then vapor source 22 is turned off and cools. A predetermined charge is loaded into vapor source 22 and vaporized completely. In continuous mode vapor source 22 is operated at a lower temperature than in batch mode and usually with the largest arsenic load. Thickness control means such as, but not limited to, optical or opto-mechanical, or electromechanical methods can be used to control vapor source 22.

When both auxiliary magnetrons are coated as desired, sputter gas is admitted through inlet 2 and controlled by valve 3. Deposition begins by sputter depositing material from auxiliary magnetrons 13 and 14 onto rotating cylindrical surrogate magnetron 12. Materials from the auxiliary sources 13 and 14 can be deposited onto surrogate magnetron 12 in several different ways. Two methods are multi-layers and sectors.

By way of further example, consider a combining of sputtered materials using various alternative methods. Multi-layering methods are described in U.S. Pat. No. 5,405,517 for the surrogate magnetron. Here each auxiliary magnetron continuously deposits one layer of its material per revolution of the surrogate magnetron 12. That material is sputtered onto substrate 19 forming thin film 25. Material composition is controlled by regulating the power levels of the auxiliary sources thus regulating the relative thicknesses of materials on the surrogate 12.

In a “sector method” using two magnetrons, and again referring to FIG. 1 by way of example, while the surrogate magnetron 12 is continuously rotating, auxiliary magnetrons 13 and 14 are powered on and off alternately so as to deposit alternate sectors of material onto surrogate 12. These sectors, as they rotate through plasma 15, deposit alternating layers of material. The power levels of the power supplies for auxiliary magnetrons 18 and 24 are adjusted as desired and are constant during deposition of their corresponding sector. If desired to prevent switching transients, dummy loads can be switched across each power supply while it is not sputtering material. The sputter power levels for surrogate 12 are a function of which sector is passing through plasma 15.

As an illustration, FIG. 4A illustrates a simplified arrangement of auxiliary sputter magnetrons and a surrogate sputter magnetron. Auxiliary magnetron 14A is powered on for only one half a rotation of rotating cylindrical surrogate magnetron 12. It deposits sector 35A. Similarly auxiliary 14B is powered on for the other half of the rotation of surrogate 16, and deposits sector 35B. Shaft angle sensing means 29 sends signal to switching circuit 27, which controls the power to each of the magnetrons 14A and 14B and 12. Shields/collimators 41 minimize edge width AB.

FIG. 3B illustrates the material edge transition width vs. angle that the auxiliary magnetrons would deposit between points A and B on a rotating surrogate 16 just after auxiliary magnetron 18 or 24 was turned off. It illustrates the sharpness of the edge of each sector. For purposes of illustration, we specify a 3-division width.

Referring to FIG. 4A and 4B, assume a sharp edge transition between sectors 35A and 35B is rotated through surrogate magnetron plasma 15. Assume a perfectly sharp edge between sector 35A and 35B is leaving the plasma and material 35B is just entering the plasma 15. Then surrogate 12 would sputter the material 35A at the rate vs. angle profile shown as CD. For illustration we assume a width of 4 units is measured for width CD. Combining profiles AB and CD gives profile EF having a 7 unit width. FIG. 3c illustrates how profile EF determines how material thicknesses deposited onto substrate 30 would vary with time (or rotation angle of surrogate 12). Such graphical data show how sharp the transition would be for the separate layers of auxiliary material deposited onto substrate 19 by surrogate sputter magnetron 12. Or putting it another way, FIG. 3C illustrates how thick the intermixing layer would be between the separate material layers 35A and 35B.

For the MEE method to work properly it is necessary to control the width of transitions EF. There is an optimum width. The transition profile is determined by the widths of the sputter plasmas 18A, 18B, and 15. These sputter plasma widths are determined by the magnet width in each corresponding magnetron as well as the distance between the auxiliary sources and the surrogate magnetron and the width of shield 41.

The number of sectors possible on the surrogate magnetron is limited by the diameter of the surrogate magnetron and the magnet widths in each magnetron. At least 2 sectors are possible. FIGS. 4D and 4E illustrate the dependency of the film structure upon the velocity of the substrate.

By way of further example, consider a sector method with a vapor source and an auxiliary magnetron with reference again to FIG. 2A, an apparatus wherein a vapor source 22 continually coats a surrogate magnetron 12 with arsenic at a predetermined rate as it is emitted through vapor slit 23. An auxiliary modulated deposition source 13G then deposits gallium sectors atop arsenic 31 as shown with material beam 40. The arsenic and gallium then pass through plasma 15 where are sputtered away. Shaft angle sensor 29 controls the modulation pattern of auxiliary source 13G.

FIG. 2B illustrates condensed arsenic 31 coated with a sector of Gallium 32. FIG. 2C illustrates the remnant 31R of Arsenic 31 that was protected by Gallium sector 32 after they passed through plasma 15. FIG. 2D illustrates arsenic remnant 31R coated with another layer of arsenic 31 and then another gallium sector 32. This Fig. illustrates that a continuing build up of arsenic remnants 31R will progress for each revolution of surrogate 12. This build up would hamper the deposition process. FIG. 2E illustrates a slight angular phase shift 34 being applied to each successive deposition of a gallium sector 32. With this new phase shift method the arsenic remnant 31R is made to sweep over the entire surface of surrogate magnetron 12. In this way any arsenic 31 buildup of remnant sectors 31R is removed by continuous sputtering.

Referring again to FIG. 1, microwave energy is emitted from feed antenna 9 and is absorbed by plasma 15. The ECR surface 30 may generate extra electrons and ions and may also add energy to electrons already present. While the ECR effect may explain the action of microwaves in lowering the surrogate plasma 28 voltage, it is understood that the theory is incomplete. All magnetrons in the deposition system can be started with or without microwave energy. The microwave source strength is then adjusted until the desired plasma discharge voltage is measured for surrogate magnetron 12. The effect of microwave energy on the auxiliary magnetrons depends on the strength of the auxiliary magnets.

By way of further example, consider the deposition of Indium Arsenide. Indium Arsenide can be deposited with a system similar to that shown in FIG. 1. The only change would be to substitute a cylindrical auxiliary magnetron identical to magnetron 24 in place of the planar magnetron 18. This cylindrical magnetron would be pre-coated with indium. All other aspects of the deposition process would be similar to example 1.

In an example of the deposition of Indium 10% Tin Oxide (ITO), it was illustrated how the present invention provides a larger range of parameter control than prior art systems. In this example it is possible to deposit ITO using MEE (migration enhance epitaxy) to deposit separate layers of Indium and Tin reactively. Or one could use reactive sputtering to coat the surrogate with both tin and indium oxide layers or suboxides. One could also reactively deposit Indium and Tin from the surrogate sources either as sectors for MEE or as separate layers. This could be done with any combination of oxide ratios on any target. And the ratio of tin to indium would be under real time control. Additionally microwave energy is used to decrease the surrogate sputter plasma voltage to decrease negative ion bombardment damage to the ITO film. Referring to FIG. 6. auxiliary magnetron 14A is pre-coated with Indium. Auxiliary magnetron 14B is pre-coated with Tin.

A typical deposition process starts with vacuum system 1 pumped to the desired vacuum. Argon sputter gas is fed through gas inlets 2 and 2i and control valves 3 and 3i into the gas isolation shields 38. All three rotating sources start continuous rotation. The power supplies to auxiliary sources 14A and 14B are turned on. If continuous double layers are desired then no shaft angle sensing means is needed and all power supplies are run at constant predetermined power levels. The power to the indium auxiliary source 14A is approximately 9 times as much as the power delivered to the tin source 14B (with correction for differences in sputter yield). The auxiliary sources build up a buffer thickness on the surrogate source 12 to buffer minor deposition rate drifts or fluctuation. The surrogate source 12 is then powered and begins continuous sputtering of ITO.

When sputter magnetrons are used, the plasma 15 voltage starts at several hundred volts. The microwave source is turned on and microwave power is emitted from feed antenna 9 to plasma 15. As the microwave power is increased, the plasma absorbs more microwave power and the power supply voltage to magnetron 12 decreases while the power remains constant. Microwave power is adjusted to give the desired plasma voltage at the selected operating power. Lowering the voltage of surrogate plasma 15 diminishes the harmful effects of the negative oxygen ion bombardment.

To aid the process, the well-known bipolar pulse mode can be used to pulse the power supplies during reactive sputtering to prevent target “poisoning” wherein the target oxidizes completely and sputtering rate decreases. Such a pulsed mode aids the surrogate magnetron sputter deposition method

As an example of superior parameter control possible, partial reactive sputtering or cathodic arcing can be applied to source 14A while source 14B is depositing unoxidized tin onto surrogate source 12. The oxidation can be completed with surrogate source 12. Argon is fed to source Indium 14A through gas inlet 2. Argon and oxygen are fed to tin source 14B through gas lines 2i and 2ii. Oxygen and argon are fed to source 12. Source 12 may not need argon as the argon from the auxiliary sources 14A and 14B may provide an adequate supply of argon to source 12. The deposition power to and gas flows to auxiliary source 14B are adjusted to partially oxidize the tin on the surface on auxiliary source 14B. Gas shields 38 prevent gases from one source from affecting any other source. The surrogate source 12 is also operated in a reactive mode to complete the oxidation as it sputters the sub-oxide it received from source 14B and the pure indium it received from source 14A onto substrate 19 to form ITO thin film 25. Microwaves from antenna 9 can lower the plasma 15 voltage to the most efficient level for the least negative ion bombardment damage, which further improves the film properties. Thus the invention provides control over more parameters for the ITO deposition process than in the prior art.

Many modifications and other embodiments of the invention will come to the mind of one skilled in the art having the benefit of the teachings presented in the foregoing descriptions and the associated drawings. Therefore, it is to be understood that the invention is not to be limited to the specific embodiments disclosed, and that modifications and alternate embodiments are intended to be included within the scope of the appended claims.

That which is claimed is:

1. A sputter deposition apparatus for depositing a film onto a substrate, the apparatus comprising a surrogate rotating magnetron having an internal magnet proximate one side of a wall for providing a magnetic field having a field strength for confining a sputter plasma capable of absorption of microwave energy, wherein the wall has a thickness sufficient for allowing a fringe magnetic field to support an electron cyclotron resonance on an opposing side thereof.

2. A sputter apparatus according to claim 1, wherein the microwave energy is directed at the sputter plasma with sufficient strength to significantly lower a discharge voltage of the sputter plasma, wherein negative ion bombardment of the film is significantly reduced.

3. A sputter apparatus according to claim 1, wherein the internal magnet is of sufficient strength to significantly decrease dynamic impedance of the sputter plasma.

4. A sputter deposition apparatus for depositing a film onto a substrate using a surrogate rotating magnetron, the apparatus comprising means for modulating a material flux from at least one auxiliary coating source onto a wall of the surrogate rotating magnetron in a desired sequence for producing sectors of auxiliary material, wherein the surrogate rotating magnetron deposits a controlled sequence of auxiliary materials onto a substrate.

5. A sputter deposition apparatus according to claim 4, further comprising means for detecting a rotation angle of the surrogate magnetron, wherein control signals can be generated for controlling the material flux sequences.

6. A sputter deposition apparatus according to claim 4, wherein the modulating means provide modulating power to the at least one coating source.

7. A sputter deposition apparatus according to claim 4, wherein the material flux modulation sequence is selected to provide migration enhanced epitaxy (MEE) thin films by depositing alternating layers of selected materials in a layered thickness for improving a crystalline structure of the film.

8. A sputter deposition apparatus according to claim 4, wherein the material flux modulation sequence is selected to provide the film having a selected quantum well structure such that the electronic performance of the film is improved.

9. A sputter deposition apparatus according to claim 4, further including means for adjusting uniformity of the modulated material flux, wherein peaks and valleys in the flux are minimized, and wherein a time between resurfacing of a surrogate magnetron surface is optimized.

10. A sputter deposition apparatus according to claim 9, wherein the adjusting means comprise a plurality of moveable planar shutters operable for intercepting predetermined portions of the modulated material flux before the material flux reaches the surrogate rotating magnetron.

11. A sputter deposition apparatus according to claim 4, further comprising a plurality of auxiliary sources, and wherein the material flux modulation is provided by continuously coating a surface of the rotating surrogate magnetron with a condensed vapor from a vapor source and pulsing at least one of the plurality of auxiliary sources such that a second film is deposited onto the condensed vapor coating in a desired pattern, the material flux sequence sputtered from the surrogate magnetron being modulated to provide a desired structure of the film.

12. A sputter deposition apparatus according to claim 11, wherein at least one of the plurality of auxiliary sources is pulsed with a controlled phase shift with respect to the rotating surrogate magnetron, and wherein the desired pulsed pattern of the auxiliary material is continuously swept over the condensed vapor coating to obliterate pattern buildup in the condensed vapor coating caused by the flux pattern from the auxiliary source.

13. A sputter deposition apparatus according to claim 4, wherein the auxiliary coating source is a cathodic arc plasma deposition source.

14. A sputter deposition apparatus according to claim 4, wherein the film comprises a thin film.

15. A deposition apparatus comprising an auxiliary coating source having heating means for melting a coating material and means for retaining the molten material until solidified, the retaining means operable for rotating the solidified material to a position suitable for coating a surface.

16. A deposition apparatus according to claim 15, wherein the auxiliary coating source is selected from the group consisting of a sputter magnetron and a cathodic arc deposition source.
